(19) United States
(12) Patent Application Publication
(10) Pub. No.: US 2025/0011624 A1
(43) Pub. Date: Jan. 9, 2025

(54) POLISHING SLURRY, AND METHOD OF MANUFACTURING SEMICONDUCTOR DEVICE

(71) Applicant: SAMSUNG ELECTRONICS CO., LTD., Suwon-si (KR)

(72) Inventors: Hyune Jea LEE, Suwon-si (KR); Sang Soo JEE, Suwon-si (KR); Kee Chang LEE, Suwon-si (KR); Jung Hoon LEE, Suwon-si (KR)

(21) Appl. No.: 18/761,170

(22) Filed: Jul. 1, 2024

(30) Foreign Application Priority Data
Jul. 3, 2023 (KR) 10-2023-0085965
Jul. 1, 2024 (KR) 10-2024-0086080

(51) Int. Cl. C09G 1/02; H01L 21/321

(52) U.S. Cl. CPC C09G 1/02; H01L 21/3212

(57) ABSTRACT

A polishing slurry and a method of manufacturing a semiconductor device using the polishing slurry. The polishing slurry includes plate-shaped particles having a Mohs hardness of less than or equal to about 5, and a spherical abrasive. The plate-shaped particles have a thermal conductivity in a dimensional direction of greater than or equal to about 10 W/mK, and the plate-shaped particles have a larger average particle size than the spherical abrasive. Also, the plate-shaped particles and the spherical abrasive are not chemically bonded to the other.

### CROSS-REFERENCE TO RELATED APPLICATION

This application claims priority to Korean Patent Application Nos. 10-2023-0085965 and 10-2024-0086080 filed in the Korean Intellectual Property Office on Jul. 3, 2023 and Jul. 1, 2024, respectively, and all the benefits accruing therefrom under 35 U.S.C. § 119, the entire contents of which are incorporated herein by reference.

### BACKGROUND

### 1. Field

A polishing slurry, and a method of manufacturing a semiconductor device using the polishing slurry.

### 2. Description of the Related Art

A semiconductor device requires a structure with a flat surface during the manufacturing process. This structure may be formed by a polishing process. The polishing process may include chemical mechanical polishing (CMP). The chemical mechanical polishing includes providing a polishing slurry containing abrasive particles between a substrate, e.g., a semiconductor substrate, to be polished and a polishing pad as the substrate in contact with the polishing pad is rotated to planarize the surface of the substrate.

With the continued advancement in semiconductor design, and in particular, high-performance and highly integrated semiconductor devices such designs or devices necessarily require fine pitch structures. Accordingly, fine abrasive particles of very small particle size range are presently being developed to effectively polish such fine pitch structures in the substrates. However, when the fine abrasive particles are used the polishing rate tends to be quite low, which significantly impacts production efficiencies. Therefore, there is a need for new methods that can achieve both effective polishing of fine pitch structures in substrates and improvement in polishing rate.

### SUMMARY

A new polishing slurry that can simultaneously improve polishing rate and effectiveness while reducing structural damage and shape deformation, e.g., surface scratches.

A method of manufacturing a semiconductor device using the polishing slurry.

A polishing slurry includes plate-shaped particles having a Mohs hardness of less than or equal to about 5, and a spherical abrasive, wherein the plate-shaped particles have a thermal conductivity in a dimensional direction of greater than or equal to about 10 Watts per meter-Kelvin (W/mK), and the plate-shaped particles have a larger average particle size than the spherical abrasive, wherein the plate-shaped particles and the spherical abrasive are not chemically bonded to the other.

The spherical abrasive has a Mohs hardness of greater than about 5.

The spherical abrasive has an average particle diameter of less than or equal to about 300 nanometers (nm).

The plate shaped particles have an average particle size of about 50 nm to about 100 micrometers (μm).

The plate-shaped particles have a thermal conductivity in the dimensional direction of greater than or equal to about 100 W/mk.

A difference in Mohs hardness between the plate-shaped particles and the spherical abrasive is greater than or equal to about 4.

The plate-shaped particles have an aspect ratio of about 3:1 to about 1000:1.

The plate-shaped particles have an anisotropic structure.

The plate-shaped particles include an inorganic material.

The plate-shaped particles include graphite, graphene, graphene oxide, hexagonal boron nitride (h-BN), or any combination thereof.

The spherical abrasive includes oxide, nitride, fluoride, carbide, or any combination thereof.

The spherical abrasive includes a metal oxide, and the metal oxide includes silicon oxide, cerium oxide, titanium oxide, zirconium oxide, aluminum oxide, molybdenum oxide, ruthenium oxide, tantalum oxide, tungsten oxide, or any combination thereof.

The spherical abrasive includes a metal nitride, and the metal nitride includes silicon nitride, aluminum nitride, titanium nitride, boron nitride (cubic structure), or any combination thereof.

The spherical abrasive includes a metal fluoride, and the metal fluoride includes calcium fluoride (CaF₂), selenium fluoride (SeF₄), tellurium fluoride (TeF₄), or any combination thereof.

The spherical abrasive includes a metal carbide, and the metal carbide includes tantalum carbide, boron carbide, or any combination thereof.

The plate-shaped particles are included in the polishing slurry in an amount of about 0.01 weight percent (wt %) to about 10 wt % based on the total weight of the polishing slurry.

The spherical abrasive is included in the polishing slurry in an amount of about 0.01 wt % to about 10 wt % based on the total weight of the polishing slurry.

The plate-shaped particles and the spherical abrasive are present in the slurry in a weight ratio of about 1:1 to about 100:1.

The polishing slurry further includes a chelating agent, an oxidizing agent, a surfactant, a dispersant, a pH adjusting agent, or any combination thereof.

A method of manufacturing a semiconductor device according to some example embodiments includes arranging a surface of a semiconductor substrate and a surface of a polishing pad proximate to the other, supplying the polishing slurry according to some example embodiments between the semiconductor substrate and the polishing pad, and polishing the surface of the semiconductor substrate by contacting the surface of the semiconductor substrate with the surface of the polishing pad.

The supplying of the polishing slurry according to some example embodiments includes supplying the polishing slurry between the semiconductor substrate and the polishing pad at a rate of about 10 milliliter per minute (ml/min) to about 1000 ml/min.

The polishing of the surface of the semiconductor substrate is conducted at a pressure to the surface of about 1 psi to about 100 psi.

The polishing slurry can polish a metal wire present at the surface of the semiconductor substrate. Accordingly, the semiconductor substrate comprises a metal wire at the surface of the semiconductor substrate, and the polishing of the surface of the semiconductor substrate polishes the metal wire.

The polishing slurry according to some example embodiments can improve polishing rate and polishing efficiency, and optionally minimize surface damage such as surface scratches and shape deformation of fine pitch structures. The polishing slurry is easy to manufacture and uses inexpensive materials, and thus, manufacturing costs may also become low.

### BRIEF DESCRIPTION OF THE DRAWINGS

FIG. 1 is a schematic view showing the operating principle of polishing a semiconductor substrate with a polishing slurry according to an example embodiment in a chemical mechanical polishing process.

FIGS. 2 to 5 are cross-sectional views showing steps for manufacturing a semiconductor device according to some example embodiments in which:

FIG. 2 represents an insulating film with an etched trench and a barrier layer;

FIG. 3 represents a filling of the etched trench of the insulating film of FIG. 2 with a metal;

FIG. 4 represents a planarized and buried metal layer of FIG. 3, the planarization conducted in accordance with an embodiment described herein; and

FIG. 5 represents an addition of a capping layer to the structure of FIG. 4.

FIG. 6 is a flowchart illustrating a method for manufacturing a semiconductor device.

FIG. 7 is a schematic block diagram of an electronic device.

### DETAILED DESCRIPTION

The invention will be described more fully hereinafter with reference to the accompanying drawings. Some example embodiments are described in detail so those of ordinary skill in the art can easily implement them and should not be construed as limited to the embodiments set forth herein. Moreover, a process or structure that is shown may be implemented in various different forms and is not limited to the example embodiments described herein. The terminology used herein is used to describe embodiments only and is not intended to limit the present disclosure. As used herein, the singular forms “a,” “an,” and “the” are intended to include the plural forms, including “at least one,” unless the content clearly indicates otherwise. Therefore, reference to “an” element in a claim followed by reference to “the” element is inclusive of one element as well as a plurality of the elements.

As used herein, “any combination thereof” refers to a mixture, a laminate, a composite, a copolymer, an alloy, a blend, a reaction product, and/or the like of constituents.

As used herein, “metal” may include a semi-metal as well as a metal.

As used herein, “Mohs hardness” is a relative value compared with reference materials (refer to https://en.wikipedia.org/wiki/Mohs_scale).

It should be understood that terms such as “comprises” and/or “comprising,” or “includes” and/or “including” or “have” are intended to designate the presence of an embodied feature, number, step, element, or any combination thereof, but does not preclude the possibility of the presence or addition of one or more other features, number, step, element, or any combination thereof.

In the drawings, the thickness of layers, films, panels, regions, etc., are exaggerated for clarity. Like reference numerals designate like elements throughout the specification.

It will be understood that when an element such as a layer, film, region, or substrate is referred to as being “on” another element, it may be directly on the other element or intervening elements may also be present. In contrast, when an element is referred to as being “directly on” another element, there are no intervening elements present.

In addition, the term “layer” as used herein includes not only a shape formed on the whole surface when viewed from a plan view, but also a shape formed on a partial surface.

As used herein, “size” means an average particle diameter in the case of a sphere and the length of the longest dimension in the case of a non-spherical shape. The size may be measured by a method well known to those skilled in the art, for example, may be measured by a particle size analyzer, or may be measured by a transmission electron micrograph or a scanning electron micrograph. Alternatively, it is possible to obtain an average particle diameter value by measuring utilizing a dynamic light scattering method, performing data analysis, counting the number of particles for each particle size range, and calculating from these data. Unless otherwise defined, the average particle diameter may refer to the diameter (D50) of particles having a cumulative volume of 50 volume % in the particle size distribution.

In the present disclosure, the term “or” is not to be construed as an exclusive meaning, and for example, “A or B” is construed to include A, B, A+B.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±10% or ±5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Advanced high-performance highly integrated semiconductor devices require fine pitch structures of about 10 nm or less. Conventional abrasive slurries including abrasive particles with a particle size of several tens of nanometers may cause damage to fine pitch structures, such as, for example, surface scratches and shape deformation. Accordingly, in order to effectively polish fine pitch structures, fine abrasive particles with a particle size of several nanometers are of interest and are being studied rather than the existing abrasive particles with a particle size of tens of nanometers. However, these fine abrasive particles have a low or inefficient polishing rate, and therefore, improvement in polishing performance is needed and sought.

A traditional method is to increase the size of the abrasive particles to increase the removal rate (RR), but this may cause many scratches and defects on the surface of the semiconductor device. In addition, it is not appropriate to use large-sized abrasive particles for polishing high-performance, highly integrated semiconductor devices that require fine pitch structures of about 10 nm or less.

Another method to increase the polishing rate is to synthesize new shaped or functional abrasive particles. However, this is cumbersome as it requires multiple synthesis steps, and of the related time and labor consumption.

On method for inducing a strong chemical bond between ceria and SiO₂ on surface of the semiconductor may be by controlling the ion valence on the surface of ceria, that is, the ratio of Ce³⁺/Ce⁴⁺. However, controlling the ion valence of the surface of ceria generally requires a high-temperature reduction reaction using hydrogen, which requires high temperature and has a risk of explosion, or doping with expensive transition metal or noble metal atoms.

The polishing slurry according to some example embodiments is not associated with any of the problems of existing methods and can be easily manufactured with inexpensive materials. In addition, excellent polishing effect and significantly improved polishing rate can be achieved when performing a polishing process using the prepared polishing slurry in accordance with an embodiment.

Specifically, the polishing slurry according to some example embodiments includes plate-shaped particles having a Mohs hardness of less than or equal to about 5, and a spherical abrasive. The plate-shaped particles have a thermal conductivity in a dimensional direction of greater than or equal to about 10 W/mK and have a larger particle (average) size than the spherical abrasive. The plate-shaped particles and the spherical abrasive are not chemically bonded to the other.

In other words, the polishing slurry according to some example embodiments may be manufactured by simple mixing of plate-shaped particles with a spherical abrasive, wherein the plate-shaped particles have a significantly lower Mohs hardness than the abrasive particles and the material to be polished, such as SiO₂ that forms a semiconductor material.

While the experimental data may suggest or Applicant believes that the plate-shaped particles do not directly participate in polishing, the construction of Applicant's claims are limited by the reported data or beliefs (hypothesis). The plate-shaped particles have a particle size larger than the abrasive particles, and also have a thermal conductivity in a dimensional direction of greater than or equal to a certain value. Here, ‘thermal conductivity in a dimensional direction means thermal conductivity in any one direction of the planar direction or the thickness direction of the plate-shaped particles. That is, if a thermal conductivity of the plate-shaped particles in either the planar direction or the thickness direction is greater than or equal to about 10 Watts per meter-Kelvin (W/mK), then a thermal conductivity in the other direction may be greater than or equal to about 10 W/mK or less.

As the abrasive, any spherical abrasive commonly used in chemical mechanical polishing processes can be used without limitation, and as the plate-shaped particles, any plate-shaped particles that meet the aforementioned specific thermal conductivity value and have a relatively low Mohs hardness can be used. Therefore, the polishing slurry according to some example embodiments does not require special processes or expensive costs for manufacturing or preparing the abrasive particles or the plate-shaped particles, and thus, can be easily manufactured at low cost by a simple mixing of readily available materials. As can be seen from the examples described below, the polishing slurry according to some example embodiments prepared have excellent polishing effect, for example, a high polishing rate without causing defects, such as, for example, surface scratches, in the presence of small-sized abrasive particles.

A Mohs hardness of the plate-shaped particles may be less than or equal to about 5.0, less than or equal to about 4.9, less than or equal to about 4.8, less than or equal to about 4.7, less than or equal to about 4.6, less than or equal to about 4.5, less than or equal to about 4.4, less than or equal to about 4.3, less than or equal to about 4.2, less than or equal to about 4.1, less than or equal to about 4.0, less than or equal to about 3.9, less than or equal to about 3.8, less than or equal to about 3.7, less than or equal to about 3.6, less than or equal to about 3.5, less than or equal to about 3.4, less than or equal to about 3.3, less than or equal to about 3.2, less than or equal to about 3.1, less than or equal to about 3.0, or less than or equal to about 2.5. The Mohs hardness of the plate-shaped particles may be greater than or equal to about 0.1, greater than or equal to about 0.2, greater than or equal to about 0.3, greater than or equal to about 0.4, or greater than or equal to about 0.5. When having a Mohs hardness within the above range, the plate-shaped particles may not participate in the actual polishing process in a general chemical mechanical polishing process because the Mohs hardness in the above range is lower than the Mohs hardness of a polishing object to be polished.

The spherical abrasive may be any spherical abrasive used in a chemical mechanical polishing process, for example, those having a Mohs hardness of greater than about 5 may be used. For example, the Mohs hardness of the spherical abrasive may be greater than or equal to about 5.5, greater than or equal to about 5.6, greater than or equal to about 5.7, greater than or equal to about 5.8, greater than or equal to about 5.9, greater than or equal to about 6.0, greater than or equal to about 6.1, greater than or equal to about 6.2, greater than or equal to about 6.3, greater than or equal to about 6.4, greater than or equal to about 6.5, or greater than or equal to about 7.0, and less than or equal to about 10. The spherical abrasive may have a Mohs hardness within the above range, and thus can participate in a practical polishing process within the polishing slurry according to some example embodiments.

In the polishing slurry according to some example embodiments, the plate-shaped particles and the spherical abrasive each have a Mohs hardness in the above ranges, so that the polishing slurry according to some example embodiments that combines them can achieve high polishing rates while minimizing damage (e.g., surface scratches) and shape deformation of the structure to be polished.

A difference in Mohs hardness between the plate-shaped particles and the spherical abrasive may be greater than or equal to about 4, for example, greater than or equal to about 4.5, greater than or equal to about 5.0, greater than or equal to about 5.5, or greater than or equal to about 6.0. Additionally, the difference in Mohs hardness between the plate-shaped particles and the abrasive particles may be less than or equal to about 1000, less than or equal to about 100, less than or equal to about 10, less than or equal to about 9.0, less than or equal to about 8.0, or less than or equal to about 7.0. When the difference in Mohs hardness between the plate-shaped particles and the spherical abrasive is within the above range, high-performance, highly integrated semiconductor devices having a fine pitch structure of about 10 nm or less may have reduced, minimized, or eliminated defects on one or more surfaces of the semiconductor devices.

The thermal conductivity in a dimensional direction of the plate-shaped particles may be greater than or equal to 10 W/mK, for example, greater than or equal to 15 W/mK, greater than or equal to about 20 W/mk, greater than or equal to about 25 W/mk, greater than or equal to about 30 W/mk, greater than or equal to about 35 W/mk, greater than or equal to about 40 W/mk, greater than or equal to about 45 W/mk, greater than or equal to about 50 W/mk, greater than or equal to about 55 W/mk, greater than or equal to about 60 W/mk, greater than or equal to about 65 W/mk, greater than or equal to about 70 W/mk, greater than or equal to about 75 W/mk, greater than or equal to about 80 W/mk, greater than or equal to about 85 W/mk, greater than or equal to about 90 W/mk, greater than or equal to about 95 W/mk, or greater than or equal to 100 W/mk The thermal conductivity in a dimensional direction of the plate-shaped particles may be less than or equal to about 95 W/mK, for example, less than or equal to about 90 W/mK, less than or equal to about 85 W/mK, less than or equal to about 80 W/mK, less than or equal to about 75 W/mK, less than or equal to about 70 W/mK, less than or equal to about 65 W/mK, less than or equal to about 60 W/mK, less than or equal to about 55 W/mK, less than or equal to about 50 W/mK, less than or equal to about 45 W/mK, less than or equal to about 40 W/mK, less than or equal to about 35 W/mK, less than or equal to about 30 W/mK, less than or equal to about 25 W/mK, or less than or equal to about 20 W/mK, but is not limited thereto.

In the polishing slurry according to some example embodiments, when the thermal conductivity of the plate-shaped particles in a dimensional direction is within the above range, and when the polishing slurry according to some example embodiments is applied to a polishing process, heat dissipation efficiency generated during the process is likely to be improved. Accordingly, it is possible to continuously perform the polishing process without stopping the polishing process, and further improving polishing efficiency.

In the polishing slurry according to some example embodiments, a size of the plate-shaped particles is larger than a size of the spherical abrasive. For example, an average diameter of the spherical abrasive may be less than or equal to about 300 nanometer (nm), for example, less than or equal to about 250 nm, less than or equal to about 200 nm, less than or equal to about 150 nm, less than or equal to about 140 nm, less than or equal to about 130 nm, less than or equal to about 120 nm, less than or equal to about 110 nm, less than or equal to about 100 nm, less than or equal to about 90 nm, less than or equal to about 80 nm, less than or equal to about 70 nm, less than or equal to about 60 nm, less than or equal to about 55 nm, less than or equal to about 50 nm, less than or equal to about 45 nm, less than or equal to about 40 nm, less than or equal to about 35 nm, less than or equal to about 30 nm, less than or equal to about 25 nm, less than or equal to about 20 nm, less than or equal to about 15 nm, less than or equal to about 10 nm, or less than or equal to about 5 nm. In addition, an average diameter of the spherical abrasive may be greater than or equal to about 1 nm, for example, greater than or equal to about 2 nm, greater than or equal to about 3 nm, greater than or equal to about 4 nm, greater than or equal to about 5 nm, greater than or equal to about 10 nm, greater than or equal to about 15 nm, greater than or equal to about 20 nm, greater than or equal to about 25 nm, greater than or equal to about 30 nm, greater than or equal to about 35 nm, greater than or equal to about 40 nm, greater than or equal to about 45 nm, or greater than or equal to about 50 nm, but is not limited to these ranges. As previously defined, the average particle diameter of the spherical particles refers to a diameter (D₅₀) of a particle with a cumulative volume of 50 volume % in the particle size distribution.

In the polishing slurry according to some example embodiments, when the size of the spherical abrasive is selected within the above ranges, the size of the plate-shaped particles is not specifically limited as long as the size of the plate-shaped particles is selected to have a particle size larger than that of the spherical abrasive. For example, a particle size of the plate-shaped particles may be within a range of about 50 nm to about 100 μm, for example, greater than or equal to about 60 nm, greater than or equal to about 70 nm, greater than or equal to about 80 nm, greater than or equal to about 90 nm, greater than or equal to about 100 nm, greater than or equal to about 200 nm, greater than or equal to about 300 nm, greater than or equal to about 400 nm, greater than or equal to about 500 nm, greater than or equal to about 1 μm, greater than or equal to about 1.5 μm, greater than or equal to about 2 μm, greater than or equal to about 2.5 μm, greater than or equal to about 3 μm, greater than or equal to about 3.5 μm, greater than or equal to about 4 μm, greater than or equal to about 4.5 μm, greater than or equal to about 5 μm, greater than or equal to about 5.5 μm, greater than or equal to about 6 μm, greater than or equal to about 7 μm, greater than or equal to about 8 μm, greater than or equal to about 9 μm, greater than or equal to about 10 μm, greater than or equal to about 20 μm, greater than or equal to about 30 μm, greater than or equal to about 40 μm, greater than or equal to about 50 μm, greater than or equal to about 60 μm, greater than or equal to about 70 μm, greater than or equal to about 80 μm, or greater than or equal to about 90 μm. A particle size of the plate-shaped particles may be less than or equal to about 100 μm, for example, less than or equal to about 90 μm, less than or equal to about 80 μm, less than or equal to about 70 μm, less than or equal to about 60 μm, less than or equal to about 50 μm, less than or equal to about 45 μm, less than or equal to about 40 μm, less than or equal to about 35 μm, less than or equal to about 30 μm, less than or equal to about 25 μm, less than or equal to about 20 μm, less than or equal to about 15 μm, less than or equal to about 10 μm, less than or equal to about 8 μm, less than or equal to about 6 μm, less than or equal to about 5 μm, less than or equal to about 4 μm, less than or equal to about 3 μm, less than or equal to about 2 μm, or less than or equal to about 1 μm, but is not limited to these ranges. As previously defined, the particle size of the plate-shaped particles refers to a length of the longest portion of the plane of the particle.

Meanwhile, the plate-shaped particles may have an aspect ratio of about 3:1 to about 1000:1. Here, the aspect ratio refers to a ratio of the longest length of the plane of the plate-shaped particle and a height (or thickness), and may be greater than or equal to about 3:1, greater than or equal to about 3.5:1, greater than or equal to about 4:1, greater than or equal to about 4.5:1, greater than or equal to about 5:1, greater than or equal to about 5.5:1, greater than or equal to about 6.0:1, greater than or equal to about 6.5:1, greater than or equal to about 7.0:1, greater than or equal to about 7.5:1, greater than or equal to about 8.0:1, greater than or equal to about 8.5:1, greater than or equal to about 9.0:1, greater than or equal to about 9.5:1, or greater than or equal to about 10:1. The plate-shaped particles may have an aspect ratio of less than or equal to about 1000:1, less than or equal to about 950:1, less than or equal to about 900:1, less than or equal to about 850:1, less than or equal to about 800:1, less than or equal to about 750:1, less than or equal to about 700:1, less than or equal to about 650:1, less than or equal to about 600:1, less than or equal to about 550:1, less than or equal to about 500:1, less than or equal to about 450:1, less than or equal to about 400:1, less than or equal to about 350:1, less than or equal to about 300:1, less than or equal to about 250:1, less than or equal to about 200:1, less than or equal to about 150:1, or less than or equal to about 100:1. When having an aspect ratio in the above range, the plate-shaped particles may implement a planar structure of a two-dimensional planar structure and/or a layered structure, and may also be suitable for loading such particles.

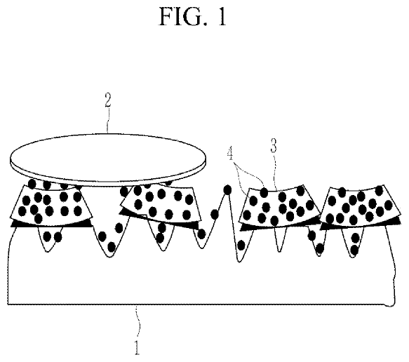

As will be described in detail below with reference to FIG. 1, the polishing slurry according to some example embodiments includes two types of particles having different shapes, sizes, and Mohs hardness. As a result, due to the complementary effect of the two types of particles by the differences in shape, size, and Mohs hardness, Applicant observed excellent polishing effects and polishing rate improvement effects that could not have been expected, e.g., based upon the individual polishing efficiencies and characteristics of each of the particles separately or in combination with other types of particles.

FIG. 1 is a schematic diagram schematically showing the principle of how a polishing slurry according to some example embodiments operates in a chemical mechanical polishing process.

Referring to FIG. 1, a polishing slurry according to some example embodiments is provided between the polishing pad 1 and the wafer 2, and the polishing slurry includes plate-shaped particles 3 and spherical abrasives 4.

As shown in FIG. 1, the plate-shaped particles 3 included in the polishing slurry according to some example embodiments have a larger particle size than the spherical abrasives 4, and in addition, due to the plate-shaped shape, it is possible to cover the concave portion of the curved portion of the polishing pad 1. This reduces the probability that spherical abrasives 4 are present in the concave portion of the polishing pad 1 and increases the probability that spherical abrasives 4 are present on the plate-shaped particles 3 and come into contact with the wafer 2. In addition, when the spherical abrasives 4 are present on the plate-shaped particles 3, pressure can be more easily transmitted to the spherical abrasives 4 through the plate-shaped particles 3. Accordingly, although the plate-shaped particles 3 do not directly participate in the polishing process, the polishing slurry according to some example embodiments including them uses abrasive particles of a relatively small particle size, thereby reducing surface scratches of the polishing object that appear when using large particle size of abrasive particles, and significantly improving the polishing rate even when small particle size of abrasive particles are used.

Meanwhile, the composite abrasive disclosed in the inventors' prior KR patent application No. 10-2023-0059347 includes a host material having a two-dimensional planar structure, a layered structure, or all of these structures corresponding to the plate-shaped particles included in the polishing slurry of some example embodiments of the present application, and abrasive particles attached to and protruding from the surface of the host material. Such a composite abrasive has abrasive particles fixed to a surface of the host material. Therefore, in the chemical mechanical polishing process using the composite abrasive, it is difficult to expect the abrasive particles fixed to the surface of the host material of polishing an object while each abrasive particle rotates individually.

On the other hand, in the polishing slurry according to some example embodiments, the plate-shaped particles 3 and the spherical abrasives 4 are not chemically bonded to each other, and the spherical abrasive 4 is present on (or disposed on) the plate-shaped particles 3, and therefore, the spherical abrasive 4 that is present on (or disposed on) the plate-shaped particles 3 is maintained in a state where it can flow freely. Accordingly, when applying the polishing slurry according to some example embodiments to a chemical mechanical polishing process, the spherical abrasives 4 not only polish the object while flowing together with the plate-shaped particles 3, but also, independently of the flow of the plate-shaped particles 3, the spherical abrasives 4 themselves rotate and polish the object. That is, in the polishing slurry according to some example embodiments, the spherical abrasives 4 can exert a polishing effect by both sliding and rolling, thereby achieving a more precise and superior polishing effect and/or a higher polishing rate.

Considering the chemical mechanical polishing process as described above, it can be understood that it is advantageous for the plate-shaped particles 3 of the polishing slurry according to some example embodiments to have a larger particle size than that of the spherical abrasives 4 and to have the aforementioned aspect ratio. That is, by having a larger particle size than the spherical abrasives 4 and/or the aforementioned aspect ratio, when applied to the chemical mechanical polishing process shown in FIG. 1, the probability that spherical abrasives 4 exist on the plate-shaped particles 3 increases, and the probability of contact with the polishing object increases, and accordingly improved polishing efficiency can be expected.

The plate-shaped particles 3 may have an anisotropic structure. When the plate-shaped particles 3 have an anisotropic structure, the contact area with the polishing object may further increase when the spherical abrasives 4 are positioned on the plate-shaped particles 3. As a result, the polishing rate (Material Removal Rate (MRR)) may further be improved.

The plate-shaped particles 3 may be an inorganic material. The inorganic material may be more advantageous than organic materials (e.g., polymers) for forming two-dimensional planar structures and/or layered structures.

For example, the plate-shaped particles 3 may include, but are not limited to, graphite, graphene, graphene oxide, hexagonal boron nitride, or any combination thereof.

The graphite may be plate-shaped or flake-shaped graphite, and may be natural graphite or synthetic graphite.

The graphene may be prepared by a mechanical method or a chemical method but is not limited thereto. In the case of the mechanical method, a mechanical method using an adhesive tape can be used as a method of obtaining a thin graphene sheet. In this case, when an adhesive tape is attached to both sides of a graphite particle and spread on both sides, the graphite is split in half, and this process may be repeated to obtain graphene with a reduced thickness.

In the case of the chemical method, a substrate on which a graphenization catalyst (e.g., metal catalyst, such as, Ni, Co, Fe, Pt, etc.) is formed on at least one surface is prepared, and after contacting the substrate with a carbon-based material (e.g., a carbon-containing polymer, etc.) as a carbon source, heat treatment is performed under an inert or reducing atmosphere to form graphene on the graphenization catalyst, and thus, to form a graphene sheet on the substrate.

The graphene or graphene oxide may be formed by stacking a plurality of sheets of 2 or more, 3 or more, 4 or more, or 5 or more, and 100 or less, 90 or less, 80 or less, 70 or less, 60 or less, or 50 or less, as long as it can provide plate-shaped particles of a certain thickness, and the number of layers is not particularly limited.

The hexagonal boron nitride may be a soft boron nitride having a plate-like structure. The hexagonal boron nitride may further include a boron oxide layer on a surface.

The plate-shaped particles 3 may have a shape suitable for having a two-dimensional planar structure or a layered structure and may have any form such as a wrinkled form, a ribbon form, a bent form, a folded form, a tube form, etc. to the extent that a two-dimensional planar structure is maintained rather than a three-dimensional form of a three-dimensional structure (for example, a sphere).

In addition, the shape of the upper surface of the plate-shaped particles 3 may be circular, elliptical, or polygonal, but is not limited thereto. The two-dimensional planar structure may include a single layer of components forming plate-shaped particles 3 that can extend along a two-dimensional plane.

The layered structure refers to a structure in which two or more planar structures are stacked at regular intervals (so that two or more planar structures are stacked and overlapped in the thickness direction of the layered structure, and the two or more planar structures extend side by side in the direction perpendicular to the thickness direction), such that a two-dimensional planar structure with a certain thickness can be formed, and the number of layers may be 2 or more, 3 or more, 4 or more, or 5 or more, and 100 or less, 90 or less, 80 or less, 70 or less, 60 or less, or 50 or less, but is not particularly limited.

These plate-shaped particles are materials that can be easily purchased commercially or easily synthesized using known methods and can be purchased or manufactured relatively inexpensively.

The spherical abrasives 4 may be any spherical abrasives that can be used in a chemical mechanical polishing process and are not limited to a specific type of abrasive.

The spherical abrasives 4 may include a metal oxide, a metal nitride, a metal fluoride, a metal carbide, or any combination thereof. For example, the metal oxide may include silicon oxide, cerium oxide, titanium oxide, zirconium oxide, aluminum oxide, molybdenum oxide, ruthenium oxide, tantalum oxide, tungsten oxide, or any combination thereof; the metal nitride may include silicon nitride, aluminum nitride fluoride, titanium nitride, boron nitride (cubic structure), or any combination thereof; the metal fluoride may include calcium fluoride (CaF₂), selenium fluoride (SeF₄), tellurium fluoride (TeF₄), or any combination thereof, and the metal carbide may include tantalum carbide, boron carbide, or any combination thereof.

Based on a total weight of the polishing slurry according to some example embodiments, the spherical abrasive may be included in an amount of about 0.01 wt % to about 10 wt %. For example, the spherical abrasive may be included in an amount of greater than or equal to about 0.01 wt %, greater than or equal to about 0.02 wt %, greater than or equal to about 0.03 wt %, greater than or equal to about 0.04 wt %, greater than or equal to about 0.05 wt %, greater than or equal to about 0.06 wt %, greater than or equal to about 0.07 wt %, greater than or equal to about 0.08 wt %, greater than or equal to about 0.09 wt %, greater than or equal to about 0.1 wt %, greater than or equal to about 0.15 wt %, greater than or equal to about 0.2 wt %, greater than or equal to about 0.3 wt %, greater than or equal to about 0.4 wt %, greater than or equal to about 0.5 wt %, or greater than or equal to about 1 wt %. In addition, the spherical shape abrasive particles may be included in an amount of less than or equal to about 10 wt %, less than or equal to about 9 wt %, less than or equal to about 8 wt %, less than or equal to about 7 wt %, less than or equal to about 6 wt %, or less than or equal to about 5 wt % based on a total weight of the polishing slurry according to some example embodiments. By including the spherical abrasive in the above range in the polishing slurry according to some example embodiments, a fine pitch structure can be effectively polished while minimizing surface damage to the polishing object, and polishing rate and polishing efficiency can also be improved.

The plate-shaped particles may be included in an amount of about 0.01 wt % to about 10 wt % based on a total weight of the polishing slurry according to some example embodiments. For example, the plate-shaped particles may be included in an amount of greater than or equal to about 0.01 wt %, greater than or equal to about 0.02 wt %, greater than or equal to about 0.03 wt %, greater than or equal to about 0.04 wt %, greater than or equal to about 0.05 wt %, greater than or equal to about 0.06 wt %, greater than or equal to about 0.07 wt %, greater than or equal to about 0.08 wt %, greater than or equal to about 0.09 wt %, greater than or equal to about 0.1 wt %, greater than or equal to about 0.15 wt %, greater than or equal to about 0.2 wt %, greater than or equal to about 0.3 wt %, greater than or equal to about 0.4 wt %, greater than or equal to about 0.5 wt %, or greater than or equal to about 1 wt %. In addition, the plate-shaped particles may be included in an amount of less than or equal to about 10 wt %, less than or equal to about 9 wt %, less than or equal to about 8 wt %, less than or equal to about 7 wt %, less than or equal to about 6 wt %, or less than or equal to about 5 wt % based on a total weight of the polishing slurry according to some example embodiments. By including plate-shaped particles in the above range in the polishing slurry according to some example embodiments, when applied to a chemical mechanical polishing process, the plate-shaped particles may effectively cover the concave portion of the polishing pad, and the majority of the spherical abrasives may be positioned on (or atop) the plate-shaped particles, thereby increasing the polishing rate and improving polishing efficiency.

In the polishing slurry according to some example embodiments, a weight ratio of the plate shaped particles to the spherical abrasive may range from about 1:1 to about 100:1. For example, the weight ratio of the plate-shaped particles to the spherical abrasive may be about 1:1 to about 90:1, about 1:1 to about 80:1, about 1:1 to about 70:1, about 1:1. to about 60:1, about 1:1 to about 50:1, about 1:1 to about 40:1, about 1:1 to about 30:1, about 1:1 to about 20:1, about 1:1 to about 10:1, about 1:1 to about 9:1, about 1:1 to about 8:1, about 1:1 to about 7:1, about 1:1 to about 6:1, about 1:1 to about 5:1, about 1:1 to about 4:1, about 1:1 to about 3:1, or about 1:1 to about 2:1. When the weight ratio of the plate-shaped particles to the spherical abrasive is within the above range, polishing efficiency is significantly improved. Moreover, there is little, if any, damage (e.g., reduction in scratching of a substrate, particularly a relatively fine structure silicon substrate). Applicant believes that when a polishing slurry including these particles is applied to a chemical mechanical polishing process in the weight ratios and differentiated particle size described herein, the plate-shaped particles may effectively cover the concave portion of the polishing pad so that the probability of the spherical abrasives present at or near the substrate surface is increased, and therefore, effective polishing and an increase in polishing rate can be expected. See, FIG. 1.

Based on the total weight of the polishing slurry according to some example embodiments, a total amount of the spherical abrasives and the plate-shaped particles may be about 0.02 wt % to about 20 wt %. For example, the total amount of the spherical abrasives and the plate-shaped particles may be greater than or equal to about 0.02 wt %, greater than or equal to about 0.03 wt %, greater than or equal to about 0.04 wt %, greater than or equal to about 0.05 wt %, greater than or equal to about 0.06 wt %, greater than or equal to about 0.07 wt %, greater than or equal to about 0.08 wt %, greater than or equal to about 0.09 wt %, greater than or equal to about 0.1 wt %, greater than or equal to about 0.15 wt %, greater than or equal to about 0.2 wt %, greater than or equal to about 0.3 wt %, greater than or equal to about 0.4 wt %, greater than or equal to about 0.5 wt %, or greater than or equal to about 1 wt % based on the total amount of polishing slurry. In addition, the total amount of the spherical abrasives and the plate-shaped particles may be included in an amount of less than or equal to about 20 wt %, less than or equal to about 15 wt %, less than or equal to about 12 wt %, less than or equal to about 10 wt %, less than or equal to about 9 wt %, less than or equal to about 8 wt %, less than or equal to about 7 wt %, less than or equal to about 6 wt %, or less than or equal to about 5 wt % based on the total amount of polishing slurry. A desired polishing rate and polishing efficiency may be obtained within the above range.

The polishing slurry according to some example embodiments can be prepared by simply mixing the plate-shaped particles and the spherical abrasive. The polishing slurry according to some example embodiments may further include other components necessary for forming the polishing slurry in addition to the plate-shaped particles and the spherical abrasive. For example, the polishing slurry may further include an additive. The additive may be, for example, a chelating agent, an oxidizing agent, a surfactant, a dispersant, a pH adjusting agent, or any combination thereof, but is not limited thereto.

The chelating agent may be, for example, phosphoric acid, nitric acid, citric acid, malonic acid, a salt thereof, or any combination thereof, but is not limited thereto.

The oxidizing agent may be, for example, hydrogen peroxide, sodium hydroxide, potassium hydroxide, or any combination thereof, but is not limited thereto.

The surfactant may be an ionic or nonionic surfactant, and may be, for example, a copolymer of ethylene oxide, a copolymer of propylene oxide, an amine compound, or any combination thereof, but is not limited thereto.

The dispersant may promote a more uniform dispersion of the plate-shaped particles and spherical abrasive, and may include, for example, a water-soluble monomer, a water-soluble oligomer, a water-soluble polymer, a metal salt, or any combination thereof. A weight average molecular weight of the water-soluble polymer may be, for example, may be, for example, less than or equal to about 10,000 g/mol, for example less than or equal to about 5000 g/mol, for example less than or equal to about 3000 g/mol, and greater than or equal to about 10 g/mol, greater than or equal to about 100 g/mol, or greater than or equal to about 1000 g/mol. The metal salt may be, for example, a copper salt, a nickel salt, a cobalt salt, a manganese salt, a tantalum salt, a ruthenium salt, or any combination thereof. The dispersant may be, for example, poly(meth)acrylic acid, poly(meth)acrylic maleic acid, polyacrylonitrile-co-butadiene-acrylic acid, carboxylic acid, sulfonic ester, sulfonic acid, phosphoric ester, cellulose, diol, a salt thereof, or any combination thereof, but is not limited thereto

The pH adjusting agent may adjust the pH of the polishing slurry, and may be, for example, an inorganic acid, an organic acid, a salt thereof, or any combination thereof. The inorganic acid or the salt thereof may include, for example, nitric acid, hydrochloric acid, phosphoric acid, sulfuric acid, hydrofluoric acid, bromic acid, iodic acid, or a salt thereof, and the organic acid or the salt thereof may include, for example, formic acid, malonic acid, maleic acid, oxalic acid, adipic acid, citric acid, acetic acid, propionic acid, fumaric acid, lactic acid, salicylic acid, benzoic acid, succinic acid, phthalic acid, butyric acid, glutaric acid, glutamic acid, glycolic acid, lactic acid, aspartic acid, tartaric acid, or a salt thereof, but is not limited thereto.

Each additive may be independently included in a small amount of, for example, about 1 ppm to about 100,000 ppm, but is not limited thereto.

The polishing slurry may further contain a solvent capable of dissolving or dispersing the above components, and the solvent may be, for example, water. The water may be, for example, distilled and/or deionized water.

The aforementioned polishing slurry may be applied when forming various structures, and may be applied, for example, to a process of polishing a conductor such as a metal wire or a process of polishing an insulator such as shallow trench isolation (STI) or an insulating layer. For example, the polishing slurry may be used to polish a conductor such as a metal wire in a semiconductor substrate, and may be used to polish a conductor such as copper (Cu), tungsten (W), or an alloy thereof.

Hereinafter, an example of a method for manufacturing a semiconductor device using the aforementioned polishing slurry will be described.

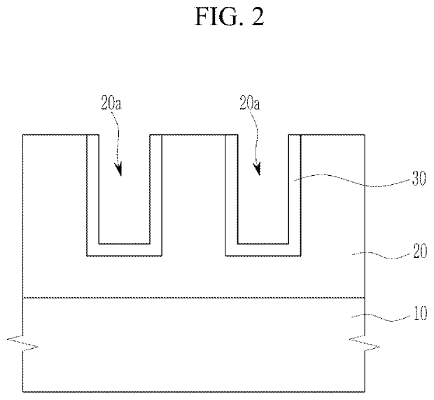

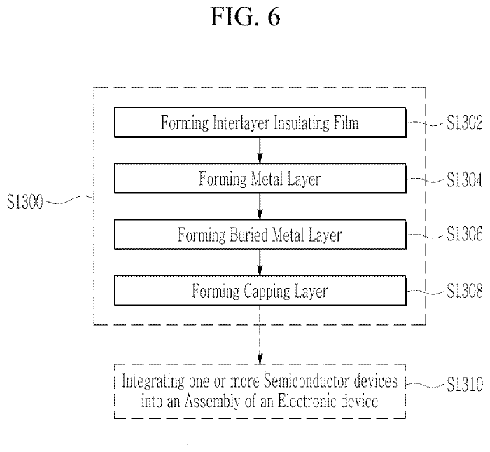

FIGS. 2 to 5 are cross-sectional views illustrating a method of manufacturing a semiconductor device according to some example embodiments. FIG. 6 is a flowchart illustrating a method according to some example embodiments including the method of manufacturing a semiconductor device (S1300) shown in at least FIGS. 2 to 5.

Referring to FIGS. 2 and 6, an interlayer insulating film 20 is formed on a semiconductor substrate 10 (e.g., a silicon substrate) (S1302). The interlayer insulating film 20 may include oxide, nitride, and/or oxynitride. The interlayer insulating film 20 may include an inorganic insulating material such as silicon oxide and/or silicon nitride or a low dielectric constant (low K) material such as SiC, SiCOH, SiCO, or SiOF. Examples of the oxide may include titanium oxide, silicon oxide, and zirconium oxide.

Subsequently, the interlayer insulating film 20 is etched to form a trench 20a. The trench 20a may have a width of less than or equal to about 10 nm (e.g., about 0.01 nm to about 10 nm wide, about 0.1 nm to about 10 nm wide, about 1.0 nm to about 10 nm wide, etc.). Next, the barrier layer 30 is formed on the wall of the trench. The barrier layer 30 may include, for example, Ta and/or TaN, but is not limited thereto.

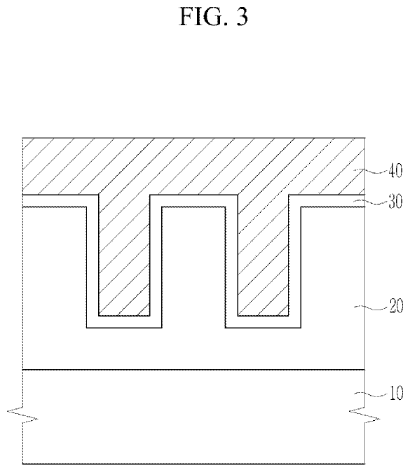

Referring to FIGS. 3 and 6, the metal layer 40 is formed by filling the trench with a metal, such as, for example, copper (Cu) (S1304).

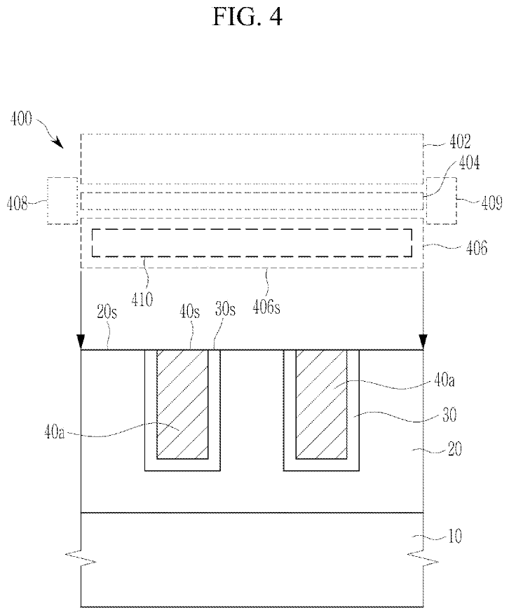

Referring to FIGS. 4 and 6, the surface 40s of the metal layer 40 is planarized to match the surface 20s of the interlayer insulating film 20 (to be on the same plane) to form a buried metal layer 40a (S1306). The planarization may also cause the surface 40s of the metal layer 40, the surface 30s of the barrier layer 30, and the surface 20s of the interlayer insulating film 20 to be coplanar or substantially coplanar with each other. Each of the surfaces 20s, 30s, and 40s may be an exposed surface of the semiconductor device exposed to the outside. The planarization can be performed by chemical mechanical polishing using a chemical mechanical polishing (CMP) equipment 400, and a polishing slurry 410 according to some example embodiments can be used. This will be described later. For example, when the barrier layer 30 is a Ta layer, and the metal layer 40 is a Cu layer, the higher polishing selectivity of Ta to Cu of the polishing slurry, the better, for example, the higher than about 50:1, the better.

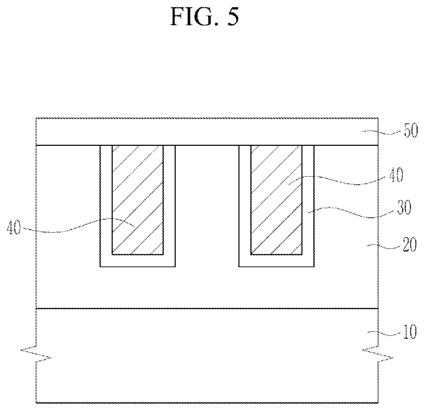

Referring to FIGS. 5 and 6, a capping layer 50 is formed on the buried metal layer 40 and the interlayer insulating film 20 (S1308). The capping layer 50 may include SiN and/or SiC but is not limited thereto.

Hereinafter, the planarization of the surface 40s of the metal layer 40 to match (e.g., to be coplanar or substantially coplanar with) at least the surface 20s of the interlayer insulating film 20 to form the buried metal layer 40a is illustrated. Referring to FIG. 4, the planarization may be performed, as described above, by the chemical mechanical polishing using the chemical mechanical polishing (CMP) equipment 400.

As shown in FIG. 4, the chemical mechanical polishing equipment 400 may include, for example, a base 402; a platen 404 rotatably provided on a surface of the base 402; a polishing pad 406 on the platen; a pad conditioner 408; and at least one polishing slurry supply device 409 disposed close to the polishing pad configured to supply the polishing slurry 410.

The platen 404 may be rotatably provided on the surface of the base 402. For example, the platen 404 may receive rotational power from a motor disposed in the lower base 402. Accordingly, the platen 404 may rotate around an imaginary rotation axis perpendicular to the surface of the platen 404. The imaginary rotation axis may be perpendicular to the surface of the base 402.

The platen 404 may include one or more supply lines through which a liquid may be injected and discharged. For example, water may be injected and discharged into the platen 404 through the supply lines to adjust a temperature of the platen 404. For example, cooling water may be injected and discharged into the platen 404 through the supply lines, and thus, lower the temperature of the platen 404 and therefore, minimize overheating. Moreover, hot water at a high temperature may be injected and discharged into the platen 404 through the supply lines, leading to increasing the temperature of the platen 404.

A polishing pad 406 may be disposed on the surface of the platen 404 to be supported by the platen 404. The polishing pad 406 may be rotated with the platen 404. The polishing pad 406 may have a rough polishing surface 406s. This polishing surface 406s may directly contact the semiconductor substrate 10, the interlayer insulating film 20, the barrier layer 30, the metal layer 40, or any combination thereof (e.g., one or more surfaces 20s, 30s, and 40s thereof) to mechanically polish a surface of the semiconductor substrate 10, the interlayer insulating film 20, the barrier layer 30, the metal layer 40, or any combination thereof (e.g., surfaces 20s, 30s, and 40s thereof). The polishing pad 406 may be a porous material having a plurality of microcavities, and the plurality of microcavities may hold the polishing slurry 410, for example, such that the polishing slurry 410 is located within an interior of the polishing pad 406, and/or microcavities of the polishing pad 406 that are exposed to a polishing surface 406s of the polishing pad 406.

The pad conditioner 408 may be disposed adjacent to the polishing pad 406 and the state of the polishing surface 406s may be maintained so that the surface of the semiconductor substrate 10, the interlayer insulating film 20, the barrier layer 30, the metal layer 40, or any combination thereof (e.g., surfaces 20s, 30s, and 40s thereof) may be polished effectively while the polishing process is performed.

The polishing slurry supply device 409 may be disposed adjacent to the polishing pad 406 and supply the polishing slurry 410 to the polishing pad 406. The polishing slurry supply device 409 may include a nozzle capable of supplying the polishing slurry 410 on the polishing pad 406 during the polishing process and a voltage supply unit capable of applying a predetermined voltage to the nozzle. The polishing slurry 410 in the nozzle can be charged by the voltage applied from the voltage supply unit and discharged toward the polishing pad 406. The polishing slurry supply device 409 may supply the aforementioned polishing slurry 410.

The chemical mechanical polishing may be, for example, performed by arranging a semiconductor substrate 10, an interlayer insulating film 20, a barrier layer 30, a metal layer 40, or any combination thereof (e.g., surfaces 20s, 30s, and 40s thereof) and a polishing pad 406 to face each other; supplying the aforementioned polishing slurry 410 from a polishing slurry supply device 409 between the semiconductor substrate 10, the interlayer insulating film 20, the barrier layer 30, the metal layer 40, or any combination thereof and the polishing pad 406; and contacting the surface of the semiconductor substrate 10, the interlayer insulating film 20, the barrier layer 30, the metal layer 40, or any combination thereof (e.g., surfaces 20s, 30s, and 40s thereof) with the polishing pad 406 (e.g., the polishing surface 406s) to perform polishing.

For example, the polishing slurry may be supplied at a rate of, for example, about 10 ml/min to about 1000 ml/min.

The polishing may be performed by mechanical friction by bringing the surface of the semiconductor substrate 10, the interlayer insulating film 20, the barrier layer 30, the metal layer 40, or any combination thereof (e.g., surfaces 20s, 30s, and 40s thereof) into contact with the polishing pad 406 (e.g., the polishing surface 406s) and rotating the polishing pad 406 in relation to the surface of the semiconductor substrate 10, the interlayer insulating film 20, the barrier layer 30, the metal layer 40, or any combination thereof (e.g., surfaces 20s, 30s, and 40s thereof). For example, a pressure of about 1 psi to about 100 psi may be applied between the polishing pad 406 and a surface of the semiconductor substrate 10, the interlayer insulating film 20, the barrier layer 30, the metal layer 40, or any combination thereof (e.g., surfaces 20s, 30s, and 40s thereof) in the step of performing polishing.

Although the method of manufacturing a semiconductor device according to some example embodiments has been described above, the method is not limited thereto and may be applied to semiconductor devices having various structures.

As described herein, a “semiconductor substrate” as described herein may include one or more structures of a semiconductor device, including for example one or more of the semiconductor substrate 10, the interlayer insulating film 20, the barrier layer 30, and/or the metal layer 40.

As described herein, a surface of a “semiconductor substrate” as described herein may include one or more surfaces of one or more structures of a semiconductor device, including for example one or more surfaces of one or more of the semiconductor substrate 10, the interlayer insulating film 20, the barrier layer 30, and/or the metal layer 40 (e.g., one or more of surfaces 20s, 30s, and/or 40s thereof).

As described herein, the step of performing polishing, performing polishing of the surface of a “semiconductor substrate,” or the like may be understood to include performing a polishing of (e.g., as part of planarizing) one or more surfaces of a semiconductor device, including for example one or more of the surfaces 20s, 40s, and/or 30s of the interlayer insulating film 20, the barrier layer 30, and/or the metal layer 40.

Referring to FIG. 6, in S1310, one or more manufactured semiconductor devices may be integrated (e.g., applied) into an assembly of an electronic device including, for example, the electronic device shown in FIG. 6. As a result, an electronic device with improved performance and integration (e.g., improved miniaturization) can be manufactured based on manufacturing one or more high-performance, highly integrated semiconductor devices (e.g., having a structure with a fine pitch). About 10 nm or less is based on having a structural surface polished using a polishing slurry according to any of the example embodiments.

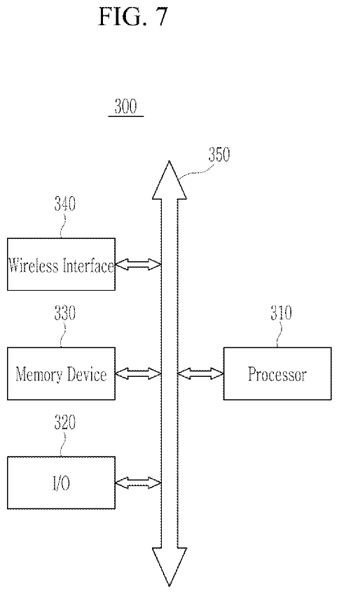

FIG. 7 is a schematic view illustrating an example of the configuration of an electronic device 300 according to some example embodiments.

Referring to FIG. 7, an electronic device 300 may include a processor 310, an input/output device (I/O) 320, a memory device 330, and a wireless interface 340, which are respectively connected to one another through a bus 350. In some example embodiments, one or more of the input/output device 320 or the wireless interface 340 may be omitted from the electronic device 300. At least one of the processor 310, the input/output device 320, the memory device 330, or the wireless interface 340 may include one or more semiconductor devices manufactured according to any of the example embodiments (e.g., using a polishing slurry according to some example embodiments). In some example embodiments, the electronic device 300 may be configured to control various equipment for manufacturing semiconductor devices (e.g., including controlling a portion or all of the chemical mechanical polishing equipment 400) and/or for manufacturing electronic devices.

The processor 310 may include at least one of a microprocessor, a digital signal processor, or a processing device similar thereto. The input/output device 320 may include at least one of a keypad, a keyboard, or a display. The memory device 330 may include a non-transitory computer readable medium configured to store a program of instructions (e.g., a solid state drive memory device). The memory device 330 may be used to store commands executed by the processor 310. For example, the memory device 330 may be used to store user data. The electronic device 300 may use the wireless interface 340 to transmit/receive data over a wireless communication network. The wireless interface 340 may include an antenna and/or a wireless transceiver.

The electronic device 300 and/or any portion thereof (e.g., the processor 310, the memory device 330, the input/output device 320, the wireless interface 340, any portion thereof, or the like) may include, may be included in, and/or may be implemented by one or more instances of processing circuitry such as hardware including logic circuits; a hardware/software combination such as a processor executing software; or any combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a solid state drive (SSD) device, storing a program of instructions, and a processor (e.g., a CPU) configured to execute the program of instructions to implement the functionality and/or methods performed by some or all of the electronic device 300 and/or any equipment and/or methods implemented and/or controlled thereby (e.g., to perform some or all of the method shown in FIGS. 2 to 5 and 13).

Hereinafter, the embodiments are illustrated in more detail with reference to examples. However, these examples are exemplary, and the scope of claims is not limited thereto.

### EXAMPLES

### Examples 1 to 5, and Comparative Examples 1 and 2: Preparation of Polishing Slurry

Two types of hexagonal boron nitride (h-BN, Shandong Pengcheng Advanced Ceramics Co., Ltd., Mohs hardness: 2, thermal conductivity: 600 W/mK) with different particle sizes (D₅₀=2 micrometers (μm) and 17 μm) as plate-shaped particles, and two types of ceria (CeO₂) with different average particle diameters (D₅₀=5 nm and 25 nm) as spherical abrasives, manufactured by Ditto Technology) (Mohs hardness: 7.5 to 8) are prepared. The plate-shaped particles and spherical abrasives are combined by changing the sizes and amounts to produce polishing slurries according to some example embodiments. All slurries use water as a solvent, and the pH is adjusted to 5 by adding nitric acid and ammonia water. Additionally, as an additive, CTAB (cetyltrimethylammonium bromide) is added at an amount of 0.5% of the weight of ceria.

The particle sizes and amounts of h-BN and ceria in the polishing slurries according to some example embodiments manufactured as described above are shown in Table 1. Additionally, for comparison, slurries including h-BN alone and ceria alone are prepared. The particle sizes and amounts of h-BN and ceria in the slurries according to the Comparative Examples are also shown in Table 1.

### Evaluation: Evaluation of Polishing Rate (MRR, Material Removal Rate)

A 40 mm×40 mm sized silicon wafer coated with an oxide film is used as a polishing wafer, and the polishing rate is evaluated using the polishing slurries prepared in the examples and comparative examples using the following polishing conditions.

The thicknesses of the wafer before and after polishing are measured, and the change in wafer thickness (Å) per unit time (1 minute) of polishing is taken as the MRR value. For thickness measurement, the center portion of the wafer is measured 5 times using a reflectometer (ST5030-SL, K-MAC) and the average value is used.

The polishing conditions are as follows:
(1) CMP equipment: POLI-400 (GnP Tech. Co.)
(2) Polishing pad: IT-2000 (KPX Chemical Co.)
(3) Rotation number of polishing head: 130 rpm
(4) Polishing platen rotation speed: 130 rpm
(5) Applied pressure: 5.5 psi
(6) Polishing slurry supply rate: 150 ml/min.

The polishing rate by the polishing slurry according to each of the Examples and Comparative Examples is measured and shown in Table 1.

TABLE 1

| | h-BN | | Ceria | | Polishing |
|---|---|---|---|---|---|
| | | Amount | | Amount | Rate |
| | D₅₀ (μm) | (wt %) | D₅₀ (nm) | (wt %) | (Å/minute) |
| Comparative | 17 | 1.32 | — | — | 3 |
| Example 1 | | | | | |
| Comparative | — | — | 25 | 0.2 | 445 |
| Example 2 | | | | | |
| Example 1 | 17 | 1.0 | 25 | 0.2 | 6,304 |
| Example 2 | 17 | 1.0 | 15 | 0.2 | 3,338 |
| Example 3 | 17 | 1.0 | 25 | 0.1 | 598 |
| Example 4 | 17 | 1.0 | 25 | 0.3 | 7,825 |
| Example 5 | 2 | 1.0 | 15 | 0.2 | 2,832 |

As shown in Table 1, the polishing rates when using the polishing slurries of Examples 1 to 5 including both plate-shaped particles (h-BN) and spherical abrasives (ceria) are at least 1.3 times to up to 17.5 times higher than when using the polishing slurry of Comparative Example 2 including ceria alone, an abrasive particle. These results are surprising in that the polishing rate can be significantly improved just by mixing h-BN, which shows little polishing performance when used alone, as can be seen from Comparative Example 1, in a small amount with abrasive particles. In particular, the particle size of ceria used in Comparative Example 2 is about 25 nm, and when abrasive particles having such a small particle size are used alone, the polishing rate is very low, but when used together with h-BN, which does not exhibit polishing performance, it shows the surprising effect of increasing the polishing rate by a whopping 14 times, as can be seen from Example 1.

Example 2 is a case in which the particle size of the ceria particles is reduced by nearly half compared to Example 1. In this case, the polishing rate is also reduced by nearly half due to the decrease in the particle size of the abrasive particles. In addition, in Example 3, compared to Example 1, the particle size of the abrasive particles is the same, but the amount of the abrasive particles is reduced by half, and in this case, the polishing rate is greatly reduced. In other words, the polishing rate can be significantly increased by mixing plate-shaped particles and a spherical abrasive, but the polishing effect itself is caused by the spherical abrasive, and the polishing rate is reduced due to a decrease in absolute amount of the spherical abrasives. This effect is also supported by Example 4. Example 4 is a case in which the amount of the abrasive particles is increased by 50% compared to Example 1, and as a result, the polishing rate also significantly increases.

Meanwhile, in the case of the polishing slurry according to Example 5, in which the size of the plate-shaped particles is greatly reduced compared to Example 2, the polishing rate is partially reduced compared to Example 2, but the polishing rate improvement effect by the combination of the two particles is sufficiently achieved.

As such, the polishing slurry according to some example embodiments includes plate-shaped particles without polishing performance together with a spherical abrasive, thereby significantly improving the polishing rate. Therefore, the polishing slurry according to some example embodiments can improve polishing efficiency by achieving a high polishing rate, particularly for a structure having a fine pitch structure. Moreover, according to some example embodiments the polishing slurry significantly reduces or minimizes the amount of damage to the fine pitch structure, e.g., semiconductor silicon substrate, in comparison to using abrasive particles, e.g., ceria, of small particle size.

While this disclosure has been described in connection with what is presently considered to be practical example embodiments, it is to be understood that the invention is not limited to the disclosed embodiments. On the contrary, it is intended to cover various modifications and equivalent arrangements included within the spirit and scope of the appended claims.

What is claimed is:

1. A polishing slurry comprising plate-shaped particles having a Mohs hardness of less than or equal to about 5, and a spherical abrasive,
wherein the plate-shaped particles have a thermal conductivity in a dimensional direction of greater than or equal to about 10 W/mK, and the plate-shaped particles have a larger average particle size than the spherical abrasive, and
wherein the plate-shaped particles and the spherical abrasive are not chemically bonded to the other.

2. The polishing slurry of claim 1, wherein the spherical abrasive has a Mohs hardness of greater than about 5.

3. The polishing slurry of claim 1, wherein a difference in Mohs hardness between the plate-shaped particles and the spherical abrasive is greater than or equal to about 4.

4. The polishing slurry of claim 1, wherein the thermal conductivity of the plate-shaped particles in the dimensional direction is greater than or equal to about 100 W/mk.

5. The polishing slurry of claim 1, wherein an average diameter of the spherical abrasive is less than or equal to about 300 nanometers.

6. The polishing slurry of claim 1, wherein an average particle size of the plate-shaped particles is from about 50 nm to about 100 μm.

7. The polishing slurry of claim 1, wherein the plate-shaped particles have an aspect ratio of about 3:1 to about 1000:1.

8. The polishing slurry of claim 1, wherein the plate-shaped particles have an anisotropic structure.

9. The polishing slurry of claim 1, wherein the plate-shaped particles comprise graphite, graphene, graphene oxide, hexagonal boron nitride, or any combination thereof.

10. The polishing slurry of claim 1, wherein the spherical abrasive comprises a metal oxide, a metal nitride, a metal fluoride, a metal carbide, or any combination thereof.

11. The polishing slurry of claim 10, wherein
the metal oxide comprises silicon oxide, cerium oxide, titanium oxide, zirconium oxide, aluminum oxide, molybdenum oxide, ruthenium oxide, tantalum oxide, tungsten oxide, or any combination thereof,
the metal nitride comprises silicon nitride, aluminum nitride, titanium nitride, boron nitride, or any combination thereof,
the metal fluoride comprises calcium fluoride, selenium fluoride, tellurium fluoride, or any combination thereof, and
the metal carbide comprises tantalum carbide, boron carbide, or any combination thereof.

12. The polishing slurry of claim 1, wherein the plate-shaped particles are included in the polishing slurry in an amount of about 0.01 wt % to about 10 wt %, and the spherical abrasive is included in the polishing slurry in an amount of about 0.01 wt % to about 10 wt %, based on the total weight of the polishing slurry.

13. The polishing slurry of claim 1, wherein an average diameter of the spherical abrasive is about 1 nm to about 100 nm, and an average particle size of the plate-shaped particles is about 1 μm to about 100 μm.

14. The polishing slurry of claim 1, wherein the plate-shaped particles and the spherical abrasive are present in the slurry in a weight ratio of about 1:1 to about 100:1.

15. The polishing slurry of claim 1, wherein the polishing slurry further comprises a chelating agent, an oxidizing agent, a surfactant, a dispersant, a pH adjusting agent, or any combination thereof.

16. A method of manufacturing a semiconductor device, comprising
arranging a surface of a semiconductor substrate and a surface of a polishing pad proximate to the other,
supplying the polishing slurry of claim 1 between the semiconductor substrate and the polishing pad, and
polishing the surface of the semiconductor substrate by contacting the surface of the semiconductor substrate with the surface of the polishing pad.

17. The method of claim 16, wherein the supplying of the polishing slurry between the semiconductor substrate and the polishing pad is conducted at a rate of about 10 ml/min to about 1000 ml/min.

18. The method of claim 16, wherein the polishing of the surface of the semiconductor substrate is conducted at a pressure to the surface of about 1 psi to about 100 psi.

19. The method of claim 16, wherein the semiconductor substrate comprises a metal wire proximate to the surface of the semiconductor substrate, and the polishing of the surface of the semiconductor substrate polishes the metal wire.

20. The method of claim 19, wherein the semiconductor substrate further comprises a barrier layer and the metal wire comprises copper, and a polishing selectivity of the barrier layer to Cu of the polishing slurry is greater than about 50:1.
